(19) United States
(12) Patent Application Publication
(10) Pub. No.: US 2003/0215045 A1
(43) Pub. Date: Nov. 20, 2003

(54) Self-adjustment device in PLL frequency synthesizer and method thereof

(75) Inventor: Kimihiko Nagata, Satsuma (JP)

Correspondence Address: ARENT FOX KINTNER PLOTKIN & KAHN, 1050 CONNECTICUT AVENUE, N.W., SUITE 400, WASHINGTON, DC, 20036, US

(73) Assignee: FUJITSU LIMITED

(21) Appl. No.: 10/419,245

(22) Filed: Apr. 21, 2003

(30) Foreign Application Priority Data
May 20, 2002 (JP) 2002-145305

(51) Int. Cl. H03D 3/24

(52) U.S. Cl. 375/376

(57) ABSTRACT

An adjustment unit in a self-adjustment device searches for an output frequency band that conforms to a reference frequency of a given signal provided from the exterior by comparing the reference frequency and the output frequency band corresponding to a first medium of a plurality of output frequency bands provided from a voltage controlled oscillator (VCO) in a PLL circuit. Depending on whether the reference frequency is higher or lower than the output frequency band corresponding to the first medium of the plurality of output frequency bands, the adjustment unit further compares the reference frequency and the output frequency band corresponding to a second medium of either a half having high output frequency bands or a half having low output frequency bands of the plurality of output frequency bands, which halves are divided having the output frequency band corresponding to the first medium as a center. Therefore, it is not necessary to search for the output frequency band that conforms to the reference frequency with respect to each of the plurality of output frequency bands that can be provided from the VCO and thus the time needed to adjust the PLL circuit, particularly the VCO, can be effectively reduced.

### BACKGROUND OF THE INVENTION

1. Field of the Invention

The present invention relates to a self-adjustment device in a phase-locked loop (PLL) frequency synthesizer. In particular, the present invention relates to a self-adjustment device for a PLL circuit in a PLL frequency synthesizer, which self-adjustment device can rapidly adjust the PLL frequency synthesizer by quickly searching for an output frequency band that conforms to a reference frequency of a given signal.

2. Description of the Related Art

A phase-locked loop (PLL) frequency synthesizer comprises a self-adjustment device and a phase locked loop (PLL) circuit, which is configured basically from a voltage controlled oscillator (VCO) that has a plurality of channels corresponding to a plurality of output frequency bands, a phase detector (PD), and a low pass filter (LPF). The self-adjustment device is used to select a roughly determined frequency band which conforms to the reference frequency of the given signal provided from the exterior and to provide the roughly determined frequency band thus selected to the VCO. The VCO is set to the roughly determined frequency band thus selected so that the PLL circuit can control the VCO so that the VCO may provide an output signal that has the reference frequency and is in phase with the given signal more effectively. This is because the PLL circuit only has to deal with the selected and limited frequency band when providing the output signal that has the reference frequency and is in phase with the given signal. In other words, by selecting the roughly determined frequency band in advance and setting an appropriate one channel of the plurality of channels corresponding to the roughly determined frequency band to the VCO, the PLL circuit can provide the output signal that has the reference frequency and is in phase with the given signal from the limited frequency band. Therefore, the PLL frequency synthesizer can adapt to a wider range of frequency band. Therefore, by using the self-adjustment device, it is possible to provide an effective PLL frequency synthesizer.

As for the self-adjustment device in the PLL frequency synthesizer of the type mentioned above according to the related art, a testing unit formed by a microcomputer, etc. is connected to the PLL frequency synthesizer. A channel switch signal is provided from the testing unit so as to switch a channel of the VCO in order to sequentially change an output frequency band (Kv line) provided from the VCO. Then, it is determined whether an oscillation frequency provided from the VCO according to a predetermined voltage selection signal conforms to a reference frequency of a given signal with respect to every output frequency band that can be provided from the VCO.

By doing so, it is possible to identify a channel corresponding to the output frequency band that conforms to the reference frequency, and the PLL circuit is adjusted so as to provide the output signal having the same frequency as the reference frequency when the predetermined voltage selection signal is provided to the VCO However, since the self-adjustment device in the PLL frequency synthesizer according to the related art is configured as mentioned above, each output frequency band that can be provided from the VCO by receiving the channel switch signal has to be searched for in order to find the output frequency band that conforms to the reference frequency and thus a comparatively long time is required for adjusting the PLL circuit, particularly the VCO. In particular, when the number of the output frequency bands (Kv lines) that can be provided from the VCO is increased so that multiple channels are available in order to improve the carrier-to-noise ratio, the search for the output frequency band that conforms to the reference frequency has to be performed on the increased number of the output frequency bands and thus a comparatively longer time is required for adjusting the PLL circuit, particularly the VCO.

### SUMMARY OF THE INVENTION

The present invention is directed to solve the problem mentioned above and an object of the present invention is to provide a self-adjustment device in the phase-locked loop (PLL) frequency synthesizer, by which self-adjustment device the voltage controlled oscillator (VCO) can be rapidly and reliably set to an appropriate one of the plurality of channels corresponding to the plurality of output frequency bands, to which the reference frequency of the given signal conforms and thus the self-adjustment time needed for the PLL frequency synthesizer can be effectively reduced.

The self-adjustment device for adjusting a phase-locked loop circuit that comprises at least one voltage controlled oscillator having a plurality of channels corresponding to a plurality of output frequency bands according to the present invention comprises; an adjustment unit providing a channel selection signal to the voltage controlled oscillator so that the voltage controlled oscillator sequentially provides one of the plurality of output frequency bands having a part of each output frequency band overlapping one over the other in accordance with the channel selection signal provided from the adjustment unit, wherein, the adjustment unit sequentially performs a plurality of search operations in order to find the output frequency band that conforms to a reference frequency of a given signal provided from the exterior, the plurality of search operations comprises a first search operation in which the reference frequency of the given signal and the output frequency band corresponding to a first medium of the plurality of output frequency bands provided from the voltage controlled oscillator are compared and, depending on the result of the first search operation, a second search operation in which the reference frequency of the given signal and the output frequency band corresponding to a second medium of one of the halves of the plurality of output frequency bands, which halves are determined by having the output frequency band corresponding to the first medium as a center dividing the halves, are compared, the plurality of search operations comprise further search operations subsequent to the second search operation, which further search operations are performed until the output frequency band that conforms to the reference frequency of the given signal is found, the adjustment unit sets an appropriate one channel of the plurality of channels corresponding to the output frequency band thus found to the voltage controlled oscillator; and the phase-locked loop circuit controls the voltage controlled oscillator so that the voltage controlled oscillator may provide an output signal that has the reference frequency and is in phase with the given signal.

According to the present invention, the adjustment unit searches for the output frequency band that conforms to the reference frequency of the given signal by comparing the reference frequency of the given signal and the output frequency band corresponding to the first medium of the plurality of output frequency bands provided from the VCO. Depending on whether the reference frequency of the given signal is higher or lower than the output frequency band corresponding to the first medium of the plurality of output frequency bands, the adjustment unit further compares the reference frequency of the given signal and an output frequency band corresponding to a second medium of either a half having higher output frequency bands or a half having lower output frequency bands of the plurality of output frequency bands, which halves are divided having the output frequency band corresponding to the first medium as a center. Therefore, it is not necessary to search for the output frequency band that conforms to the reference frequency of the given signal with respect each of the plurality of output frequency bands that can be provided from the VCO and thus the time needed to adjust the PLL circuit, particularly the VCO, can be effectively reduced.

In the self-adjustment device in the PLL frequency synthesizer according to the present invention, the adjustment unit may determine a predetermined search time for the first search operation and may also determine a predetermined search time for a subsequent search operation longer than the predetermined search time for the first search operation, if necessary.

According to the present invention, since the predetermined search times for the search operations subsequent to the first search operation, which is performed with respect to the output frequency band corresponding to the first medium of the plurality of output frequency bands, may be made longer than the predetermined search time for the first search operation, the first search operation may be performed rapidly in order to roughly determine the output frequency band that conforms to the reference frequency of the given signal and the subsequent search operations may be performed in order to determine the output frequency band that conforms to the reference frequency of the given signal in more detail during the longer search time. Therefore, it is not necessary to search for the output frequency band that conforms to the reference frequency of the given signal with respect to each of the plurality of output frequency bands that can be provided from the VCO and thus the time needed to adjust the PLL circuit, particularly the VCO, can be effectively reduced.

In the self-adjustment device in the PLL frequency synthesizer according to the present invention, the adjustment unit may determine a predetermined search time for a first search operation and may determine a predetermined search time for the subsequent search operation exponentially longer than the predetermined search time for the first search operation, if necessary.

According to the present invention, since the predetermined search times for the search operations subsequent to the first search operation, which is performed with respect to the output frequency band corresponding to the first medium of the plurality of output frequency bands, may be made exponentially longer than the predetermined search time for the first search operation, the first search operation may be performed extremely rapidly in order to roughly determine the output frequency band which conforms to the reference frequency of the given signal and the subsequent search operations may be performed in order to determine the output frequency band which conforms to the reference frequency of the given signal in more detail during the exponentially longer search time. Therefore, it is not necessary to search for the output frequency band that conforms to the given reference with respect to each of the plurality of output frequency bands that can be provided from the VCO and thus the time needed to adjust the PLL circuit, particularly the VCO, can be effectively reduced.

In the self-adjustment device in the PLL frequency synthesizer according to the present invention, the adjustment unit may comprise a timer circuit determining the predetermined search times for respective search operations and a counting circuit counting the reference frequency of the given signal provided from the exterior and a comparison frequency of an output signal provided from said VCO in the PLL frequency synthesizer provided to the adjustment unit during the predetermined search time determined in the timer circuit, if necessary.

According to the present invention, since the adjustment unit may count the reference frequency of the given signal provided from the exterior and the comparison frequency of the output signal provided from the VCO in the counting circuit during the search time determined in the timer circuit, it may be possible to determine the search times appropriate to respective search operations in advance and thus rapid and secure adjustment of the PLL frequency synthesizer, in particular, the VCO, may be possible.

In the self-adjustment device in the PLL frequency synthesizer according to the present invention, the timer circuit may determine the predetermined search time according to an input signal provided from the exterior.

According to the present invention, since the timer circuit may determine the predetermined search time according to the input signal provided from the exterior, it may be possible to adjust the search time according to the operation status or other circuits connected thereto, etc. and thus it may be possible to perform a rapid and secure adjustment operation on the PLL frequency synthesizer.

The method of adjusting a phase-locked loop circuit that comprises at least one voltage controlled oscillator having a plurality of channels corresponding to a plurality of output frequency bands comprising the steps of: a) providing a channel selection signal to the voltage controlled oscillator in the phase-locked loop circuit so that the voltage controlled oscillator sequentially provides one of a plurality of output frequency bands having a part of each output frequency band overlapping one over the other in accordance with the channel selection signal provided, and b) sequentially performing a plurality of search operations in order to find an output frequency band that conforms to a reference frequency of a given signal provided from the exterior, wherein the step b) comprises the sub-steps of: c) comparing the reference frequency of the given signal and the output frequency band corresponding to a first medium of the plurality of output frequency bands and further, d) comparing the reference frequency of the given signal and the output frequency band corresponding to a second medium of one of the halves of the plurality of output frequency bands, which halves are determined by having the output frequency band corresponding to the first medium as a center dividing the halves, depending on the result of the previous step, e) repeating the step d) until the output frequency band that conforms to the reference frequency of the given signal is found, f) setting an appropriate one channel of the plurality of channels corresponding to the output frequency band thus found to the voltage controlled oscillator, and g) controlling the voltage controlled oscillator so that the voltage controlled oscillator may provide an output signal that has the reference frequency and in phase with the given signal.

### BRIEF DESCRIPTION OF THE DRAWINGS

Other objects, advantages, and further features of the present invention will become more apparent as the description proceeds taken in conjunction with the accompanying drawings in which:

FIG. 1 is an overall block circuit diagram of a PLL frequency synthesizer comprising a self-adjustment device and a PLL circuit according to a first embodiment of the present invention;

FIG. 2 is a block circuit diagram of a calculation part in the self-adjustment device in the PLL frequency synthesizer shown in FIG. 1;

FIG. 3 is a block circuit diagram of a phase management part in the self-adjustment device in the PLL frequency synthesizer shown in FIG. 1;

FIG. 4 is a diagram illustrating output frequency characteristics of the voltage controlled oscillator shown in FIG. 1;

FIG. 5 is a conceptual diagram illustrating the relation between each output frequency band shown in FIG. 4;

FIG. 6 is a diagram illustrating the manner in which a search operation for searching for the output frequency band that conforms to a reference frequency is performed in the self-adjustment device in the PLL frequency synthesizer shown in FIG. 1;

FIG. 7 is a timing chart of the search operation shown in FIG. 6;

FIG. 8 is an operational flow chart of the search operation shown in FIG. 6;

FIG. 9 is a diagram illustrating the manner in which a search operation for searching for the output frequency band that conforms to a reference frequency is performed in a self-adjustment device for a PLL frequency synthesizer according to a second embodiment of the present invention;

FIG. 10 is a conceptual diagram illustrating the relation between each output frequency band in the self-adjustment device in the PLL frequency synthesizer according to the second embodiment of the present invention; and

FIG. 11 is a timing chart of the search operation of the self-adjustment device in the PLL frequency synthesizer according to the second embodiment of the present invention.

### DETAILED DESCRIPTION OF THE PREFERRED EMBODIMENTS

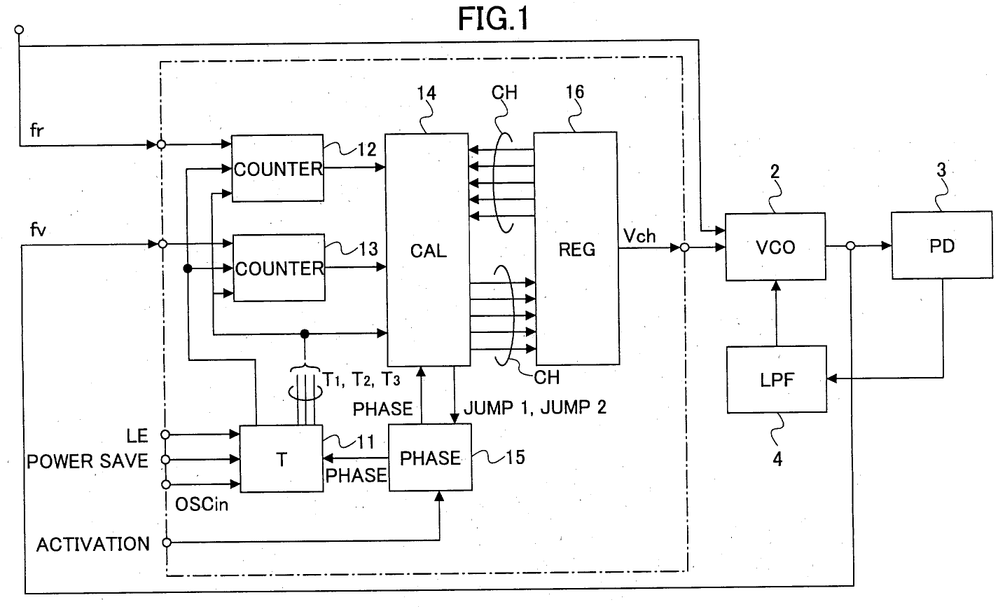

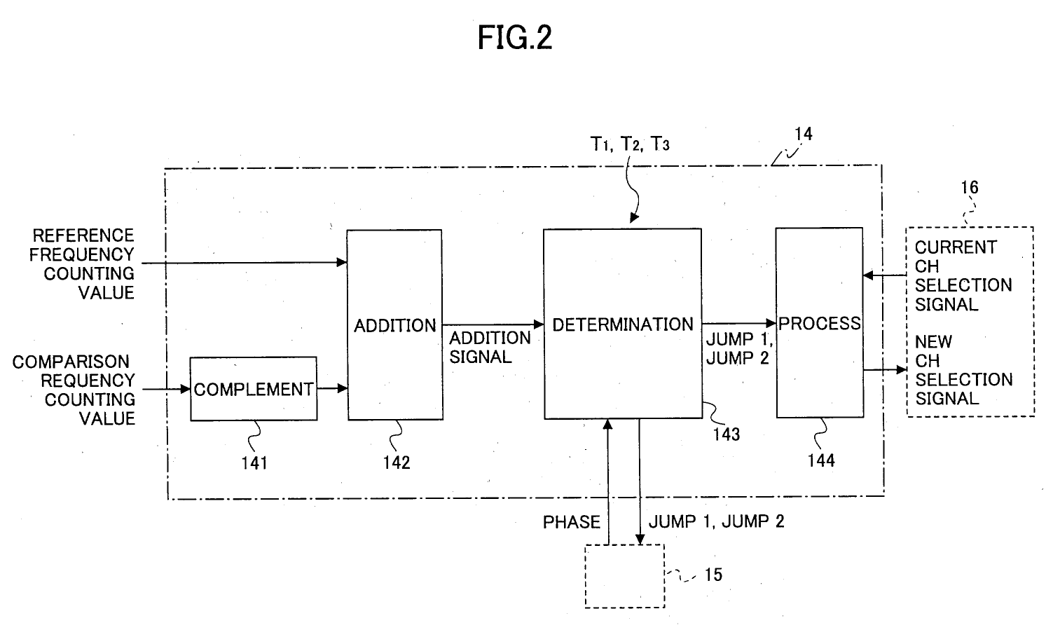

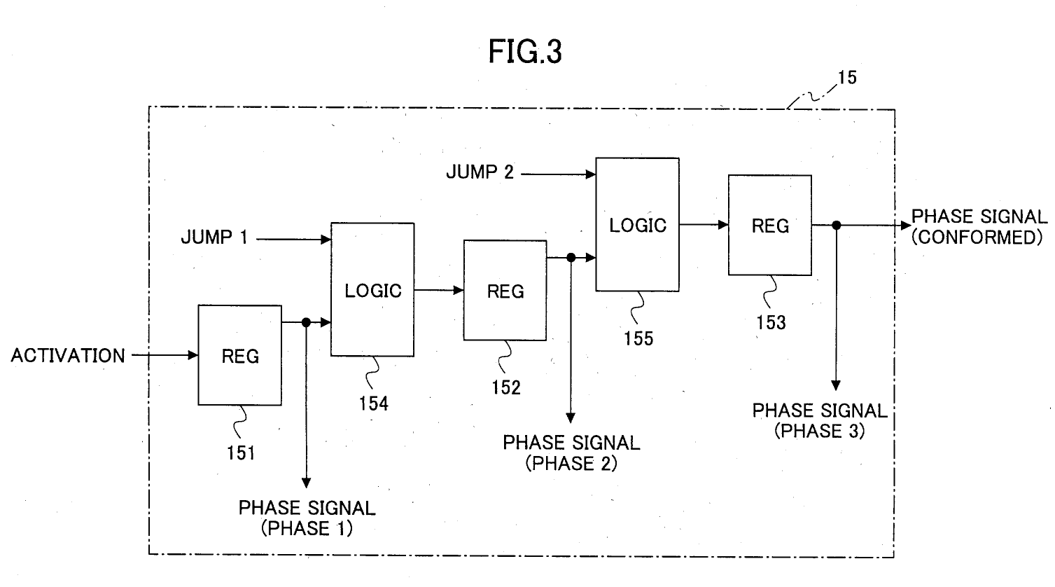

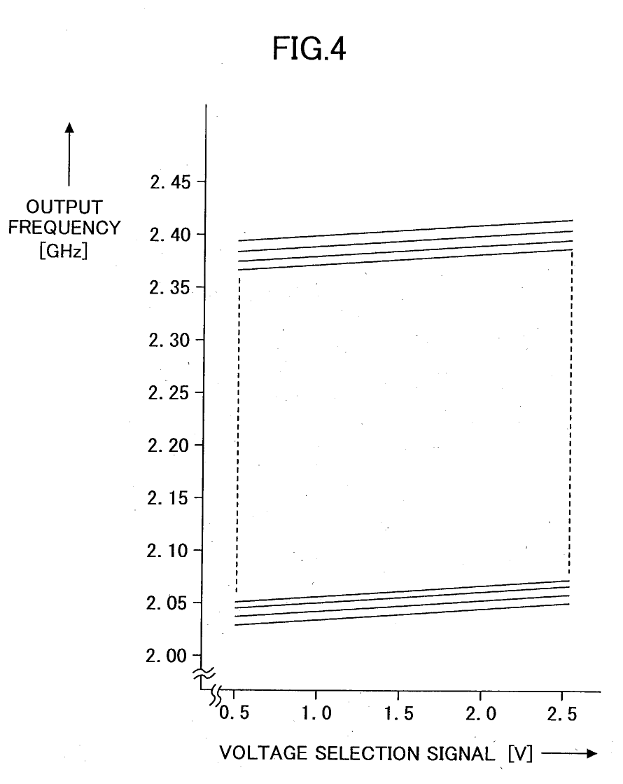

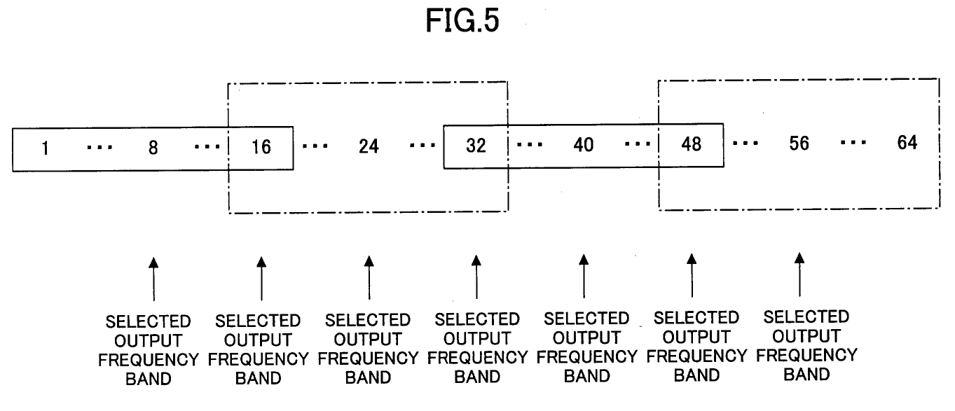

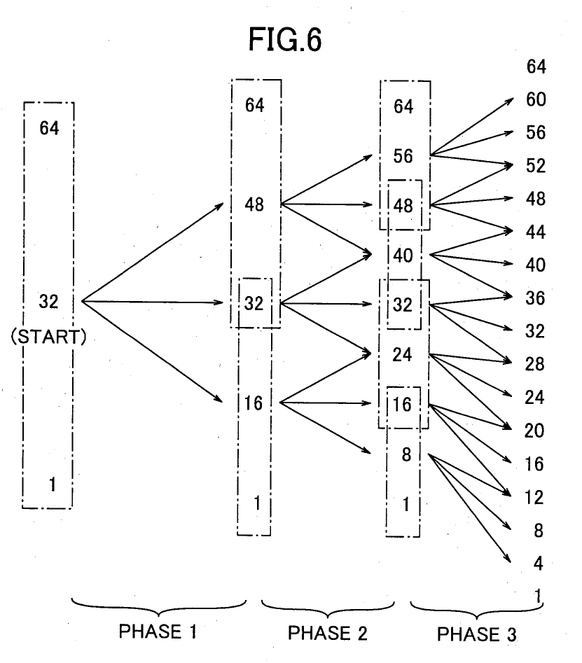

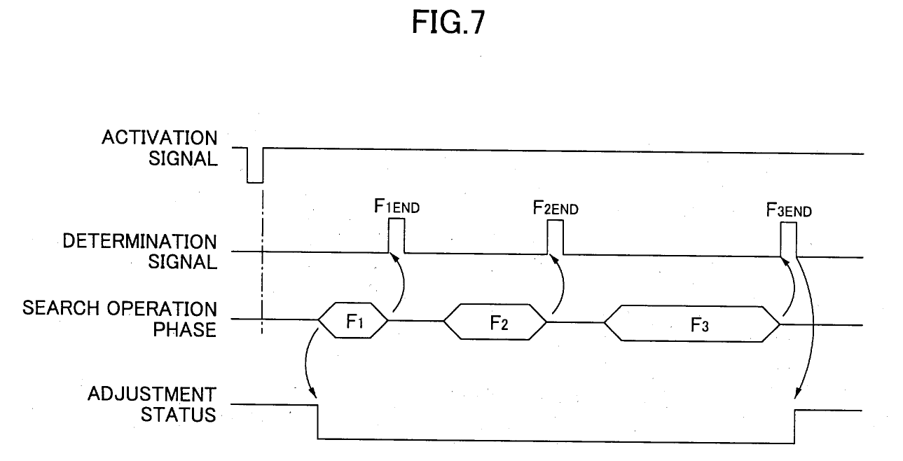

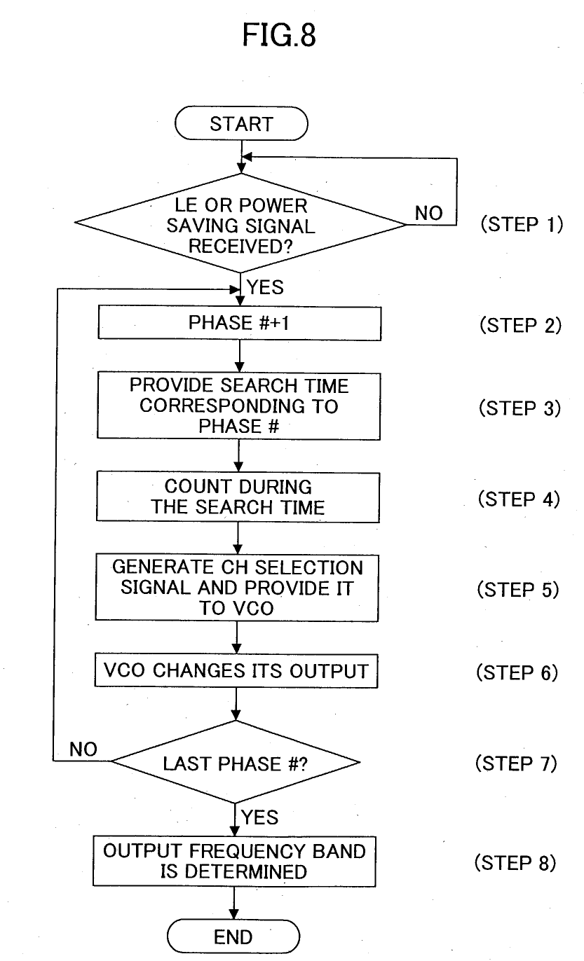

The following are descriptions of a self-adjustment device in a PLL frequency synthesizer according to a first embodiment of the present invention and a method thereof with reference to FIG. 1 through FIG. 8. FIG. 1 is an overall block circuit diagram of the PLL frequency synthesizer comprising the self-adjustment device and a phase-locked loop (PLL) circuit according to the first embodiment. FIG. 2 is a block circuit diagram in a calculation part in the self-adjustment device of the PLL frequency synthesizer shown in FIG. 1. FIG. 3 is a block circuit diagram of a phase management part in the self-adjustment device in the PLL frequency synthesizer shown in FIG. 1. FIG. 4 is a diagram illustrating output frequency band characteristics of a voltage controlled oscillator shown in FIG. 1. FIG. 5 is a conceptual diagram illustrating the relation between each output frequency band shown in FIG. 4. FIG. 6 is a diagram illustrating the manner in which a search operation for searching an output frequency band that conforms to a reference frequency of a given signal is performed in the self-adjustment device in the PLL frequency synthesizer shown in FIG. 1. FIG. 7 is a timing chart of the search operation shown in FIG. 6. FIG. 8 is an operational flow chart of the search operation shown in FIG. 6.

The PLL frequency synthesizer comprises the self-adjustment device according to the first embodiment of the present invention and the PLL circuit, which is configured basically of a voltage controlled oscillator (VCO) 2 that has a plurality of channels corresponding to a plurality of output frequency bands, a phase detector (PD) 3, and a low pass filter (LPF) 4. The self-adjustment device selects a roughly determined frequency band that conforms to the reference frequency of the given signal provided from the exterior and provides the roughly determined frequency band thus selected to the VCO of the PLL circuit. Then, the VCO 2 in the PLL circuit is set to the roughly determined frequency band thus selected so that the PLL circuit can control the VCO so that the VCO may provide an output signal that has the reference frequency and is in phase with the given signal more effectively. This is because the PLL circuit only has to deal with the selected and limited frequency band when providing an output signal that has the reference frequency and is in phase with the given signal. In other words, by selecting the roughly determined frequency band in advance and setting an appropriate one channel of the plurality of channels corresponding to the roughly determined frequency band thus selected, the PLL circuit can provide the output signal that has the reference frequency and is in phase with the given signal from the limited frequency band. Therefore, the PLL frequency synthesizer can adapt to a wider range of frequency band and by using an adjustment device, it is possible to provide an effective PLL frequency synthesizer.

The self-adjustment device in the PLL frequency synthesizer according to the first embodiment of the present invention includes an adjustment unit 1. The VCO 2 sequentially provides a plurality of output frequency bands (F1, . . . , F64) having a part of each adjacent output frequency band (F1/F2, . . . , F63/F64) overlapping one another (see FIG. 5) when receiving the channel switch signal provided from the exterior. The adjustment unit 1 adjusts the VCO 2 by providing the channel selection signal to the VCO 2 under a certain condition.

The adjustment unit 1 includes a timer part (T) 11, a reference frequency counting part 12, a comparison frequency counting part 13, a calculation part (CAL) 14, a phase management part 15, and an interface register (REG) 16. The timer part 11 determines search times T1, T2, and T3 based on a load erasable (LE) signal provided from the exterior and a divided signal (OSCin) provided from an oscillator (not shown). The reference frequency counting part 12 counts a reference frequency signal fr provided from the exterior when receiving an activation signal from the timing part 11 as a trigger. The comparison frequency counting part 13 counts a comparison frequency signal fr provided from the VCO 2 when receiving the activation signal from the timing part 11 as a trigger. The calculation part 14 calculates a channel selection signal CH based on the counted reference frequency signal fr, the counted comparison frequency signal fv, and the search times T1, T2, and T3. The phase management part 15 manages a phase 1, a phase 2, or a phase 3 of the search operation, which is determined by the channel selection signal CH provided from the calculation part 14 and provides a phase signal corresponding to the phase 1, the phase 2, or the phase 3, respectively, to the timer part 11 and the calculation part 14. The interface register 16 stores the channel selection signal CH calculated in the calculation part 14 and provides a voltage selection signal Vch to the VCO 2 by converting the channel selection signal CH to a voltage of a certain value, which is an analog signal.

In addition to the LE signal and the divided signal OSCin, the timer part 11 receives a circuit power saving signal. When receiving the LE signal and the circuit power saving signal as a activation signal, the timer part 11 determines the search times T1, T2, and T3 as 10 microseconds, 20 microseconds, and 40 microseconds, respectively.

The calculation part 14 includes a complement generation part 141, an addition part 142, a determination part 143, and a process part 144. The complement generation part 141 calculates 2's complements of the comparison frequency counting value obtained in the comparison frequency counting part 13. The addition part 142 adds the 2's complements of the comparison frequency counting value to the reference frequency counting value obtained from the reference frequency counting part 12. The determination part 143 provides process signals JUMP 1, JUMP 2 to the phase management part 15, which process signals permit a transition to the next phase (either the phase 2 or the phase 3) that is the next output frequency band, based on the addition signal provided from the addition part 142 and the phase signal provided from the phase management part 15. The process part 144 receives the channel selection signal CH stored in the interface register 16 (i.e. the output frequency band corresponding to the channel, on which the search operation is currently performed) and provides a new channel selection signal CH to the interface register 16.

The phase management part 15 includes a first register 151, a second register 152, and a third register 153, which are serially connected. A first logic circuit 154 is provided between the first register 151 and the second register 152 and a second logic circuit 155 is provided between the second register 152 and the third register 153. The first register 151 receives an activation signal. The first logic circuit 154 receives the process signal JUMP 1 and the second logic circuit 155 receives the process signal JUMP 2, both JUMP 1 and JUMP 2 being provided from the calculation part 14.

With reference to FIG. 8, a description of an operation of the self-adjustment device in the PLL frequency synthesizer according to the first embodiment that is configured as mentioned above is provided in the following. In other words, a description of an operation for searching for the output frequency band that conforms to the reference frequency is provided in the following.

As an assumption, the VCO 2 is provided with 64 channels and can provide output frequency bands F1, F2, . . . , F64 corresponding to 64 channels (see FIG. 4). The adjustment unit 1 provides the voltage selection signal Vch, which is converted from the channel selection signal CH, to the VCO 2 so that the VCO 2 provides the output frequency bands F1, . . . , F64 having a part of the neighboring frequency bands F1/F2, . . . , F63/F64 overlapping one over the other as Kv lines (see FIG. 5).

First, the timer part 11 in the adjustment unit 1 determines whether the LE signal or the circuit power saving signal is provided (step 1). If either the LE signal or the circuit power saving signal is provided to the timer part 11 (step 1, yes), the activation signal is provided to the phase management part 15 and the phase 1 is determined (step 2). Then, the phase signal corresponding to the phase 1 is provided to the timer part 11 and the calculation part 14, respectively. Then, the timer part 11 provides the reference frequency counting part 12, the comparison frequency counting part 13, and the calculation part 14, respectively, with the search time T1 (=10 microseconds) corresponding to the phase 1 of the phase signal. Also, the timer part 11 provides the activation signal to the reference frequency counting part 12 and the comparison frequency counting part 13 (step 3). When receiving the activation signal provided from the timer part 11, the reference frequency counting part 12 and the comparison frequency counting part 13 count the reference frequency fr and the comparison frequency fv (which corresponds to the output frequency band F32) during the search time T1 (=10 microseconds) and provide the reference frequency counting value and the comparison frequency counting value, respectively, to the calculation part 14. The counting accuracy depends on the search time T1 of the phase 1 (10 microseconds), the search time T2 of the phase 2 (20 microseconds), and search time T3 of the phase 3 (40 microseconds) determined in the phase management part 15 (step 4).

The complement generation part 141 in the calculation part 14 obtains complements of the comparison frequency counting value by a positive/negative conversion. The addition part 142 in the calculation part 14 adds the converted comparison frequency counting value to the reference frequency counting value and generates the addition signal. The determination part 143 in the calculation part 14 generates the process signals JUMP 1, JUMP 2 that permit transition to the next phase, which is phase 2, based on the addition signal, the phase signal (corresponding to the phase 1) provided from the phase management part 15, and the search time T1 (=10 microseconds). The process part 144 in the calculation part 14 provides a new/modified channel selection signal CH to the interface register 16 based on the process signals JUMP 1, JUMP 2 and the channel selection signal CH stored in the interface register 16 (i.e. the currently selected channel selection signal CH).

In more detail, when the value of the addition signal generated in the addition part 142 is “0”, then the output frequency band F32 is selected as it is. When the value of the addition signal is “positive”, this indicates that the frequency of the reference frequency signal fr is higher than the output frequency band F32, therefore, the output frequency band F48 is selected by increasing the output of the VCO 2. When the value of the addition signal is “negative”, this indicates that the frequency of the comparison frequency band fv (i.e. the output frequency band F32) is higher than the frequency of the reference frequency signal fr, therefore, the output frequency band F16 is selected by decreasing the output of the VCO 2.

When the output frequency bands F16, F48 are selected, the process signal JUMP 1 is provided to the phase management part 15 and the process part 144, respectively, from the determination part 143. Then, the new/modified channel selection signal CH, which is modified from the previously selected channel selection signal CH, is provided from the process part 144 to the interface register 16. On the other hand, when the output frequency band F32 is selected, the process signal JUMP 1 is provided to the process part 144 and the process part 144 provides the currently selected channel selection signal CH, i.e. the voltage selection signal Vch that is converted from the currently selected channel selection signal CH, to the VCO 2 through the interface register 16 (step 5). The VCO 2 changes its output according to the provided voltage selection signal Vch (step 6).

When the process signal JUMP 1 is provided to the phase management part 15, it is determined whether the process is in the last phase, i.e. phase 3, or not (step 7). When it is determined that it is not in the last phase (step 7, no), the process returns to step 2 and the operation as explained above (step 2 through step 7) is repeated having the search level changed to phase 2 from phase 1. The search operation for phase 2 is performed during search time T2 (=20 microseconds), which is longer than the search time T1 (=10 microseconds) (see FIG. 6 and FIG. 7). The reference frequency signal fr and the comparison frequency signal fv are counted in the reference frequency counting part 12 and the comparison frequency counting part 13, respectively, during this search time T2. Since the search time T2 is longer than the search time T1, more time is devoted for searching for the output frequency band that conforms to the reference frequency This indicates that the difference between the reference frequency signal fr and the comparison frequency signal fv, which is referred to as resolution, can be calculated in more detail (see FIG. 6).

After transitioning to phase 3 from phase 2, the reference frequency signal fr and the comparison frequency signal fv are counted in the reference frequency counting part 12 and the comparison frequency counting part 13, respectively, during the search time T3 (=40 microseconds), which is longer than search time T2. Therefore it is possible to calculate the difference (resolution) between the reference frequency signal fr and the comparison frequency signal fv in further detail (see FIG. 6 and FIG. 7).

When it is determined that the process is in the last phase, i.e. phase 3, (step 7, yes), the output frequency band is determined (step 8) and the process ends.

As described, by progressively reducing the difference (resolution) between the reference frequency signal fr and the comparison frequency signal fv by increasing the search time from T1 (10 microseconds) to T3 (40 microseconds) as the search operation level of the phase progresses (i.e. phase 1 to phase 2 and phase 2 to phase 3), the time needed for adjusting the PLL circuit, particularly the VCO 2, i.e. the time needed for searching for the output frequency band that conforms to the reference frequency, is effectively reduced. Here, the reduction in the difference (resolution) between the reference frequency signal fr and the comparison frequency signal fv indicates that the accuracy of determining the output frequency band, which is provided from the VCO 2 and which conforms to the reference frequency, is improved.

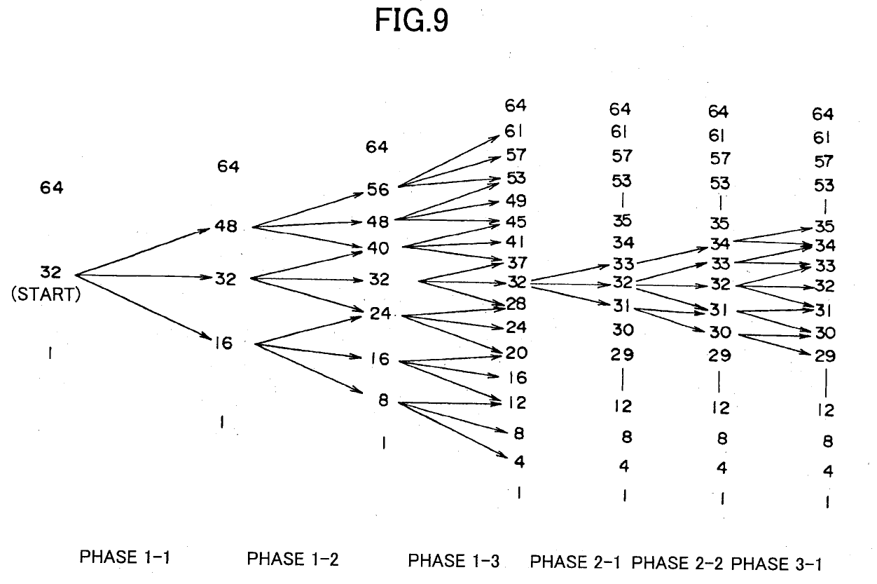

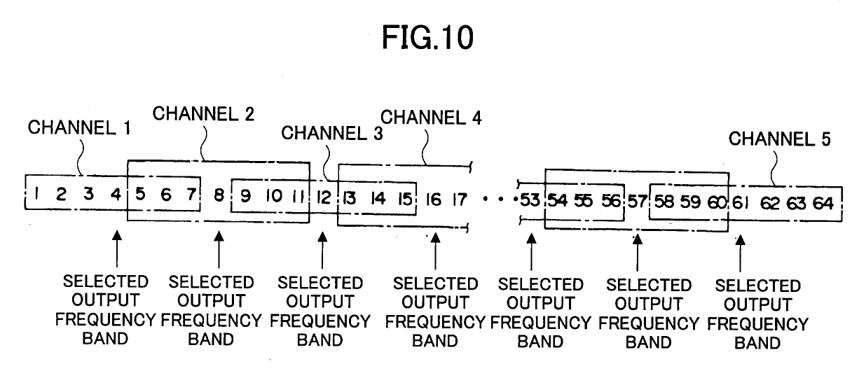

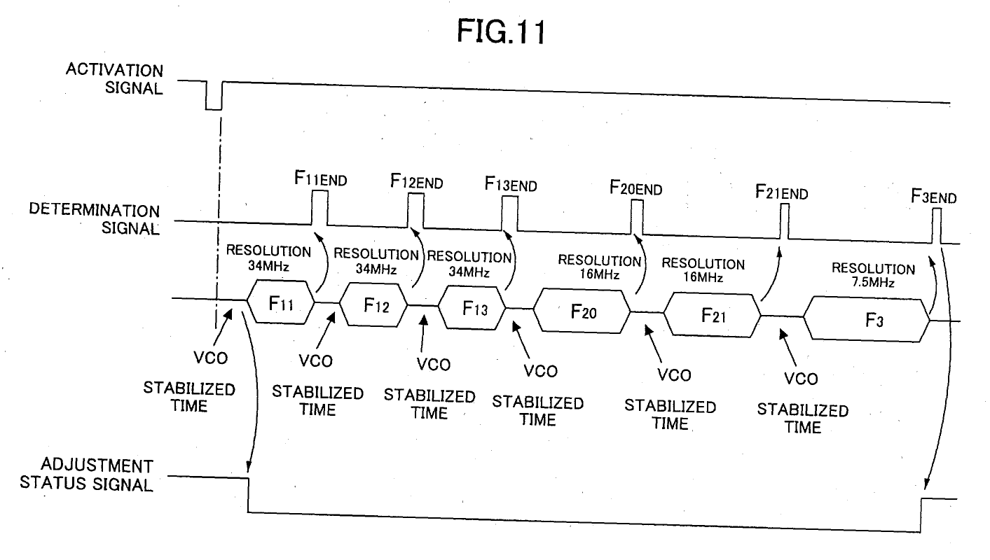

A self-adjustment device in the PLL frequency synthesizer according to a second embodiment of the present invention is described with reference to FIG. 9 through FIG. 11. FIG. 9 is a diagram illustrating the manner in which a search operation for searching for an output frequency band that conforms to a reference frequency signal is performed in the self-adjustment device in the PLL frequency synthesizer according to the second embodiment of the present invention. FIG. 10 is a conceptual diagram illustrating the relation between each output frequency band in the second embodiment. FIG. 11 is a timing chart of the search operation of the self-adjustment device in the PLL frequency synthesizer according to the second embodiment.

The second embodiment of the self-adjustment device in the PLL frequency synthesizer described in FIG. 9 through FIG. 11 is configured similarly as the first embodiment of the present invention shown in FIG. 1. Therefore, the self-adjustment device in the PLL frequency synthesizer according to the second embodiment comprises an adjustment unit 1 connected to a voltage controlled oscillator (VCO) 2 configuring a phase-locked loop (PLL) circuit. The PLL circuit further comprises a phase detector (PD) 3, and a low pass filter (LPF) 4. In addition to the configuration mentioned above, a phase management part 15 in the adjustment unit 1 determines a total of 6 phases, i.e., the phase 1-1, the phase 1-2, the phase 1-3, the phase 2-1, the phase 2-2, and the phase 3-1. A calculation part 14 in the adjustment unit 1 performs the search operation based on 6 phases. The manner in which the search operation is performed is shown in FIG. 9. As shown in FIG. 9, by increasing the number of search operation phases, it is possible to determine the output frequency with higher accuracy.

Further, since it is possible to digitally determine the relation between the reference frequency signal fr and the comparison frequency signal fv by adding the comparison frequency counting value obtained from the comparison frequency counting part 13 to the reference frequency counting value obtained from the reference frequency counting part 12, it is possible to detect more accurately whether the frequency of the reference frequency signal fr is higher than the frequency of the comparison frequency signal fv or the frequency of the comparison frequency signal Fv is higher than the frequency of the reference frequency signal fr.

Further, the present invention is not limited to the above-described embodiments, and variations and modifications may be made without departing from the scope of the present invention.

The present application is based on Japanese priority application No. 2002-145305, filed on May 20, 2002, the entire contents of which are hereby incorporated by reference.

What is claimed is:

1. A self-adjustment device for adjusting a phase-locked loop circuit that comprises at least one voltage controlled oscillator having a plurality of channels corresponding to a plurality of output frequency bands comprising:
an adjustment unit providing a channel selection signal to said voltage controlled oscillator so that said voltage controlled oscillator sequentially provides one of the plurality of output frequency bands having a part of each output frequency band overlapping one over the other in accordance with the channel selection signal provided from said adjustment unit, wherein,
said adjustment unit sequentially performs a plurality of search operations in order to find the output frequency band that conforms to a reference frequency of a given signal provided from the exterior;
the plurality of search operations comprises a first search operation in which the reference frequency of the given signal and the output frequency band corresponding to a first medium of the plurality of output frequency bands provided from said voltage controlled oscillator are compared and, depending on the result of the first search operation, a second search operation in which the reference frequency of the given signal and the output frequency band corresponding to a second medium of one of the halves of the plurality of output frequency bands, which halves are determined by having the output frequency band corresponding to the first medium as a center dividing the halves, are compared;
the plurality of search operations comprise further search operations subsequent to the second search operation, which further search operations are performed until the output frequency band that conforms to the reference frequency of the given signal is found;
said adjustment unit sets an appropriate one channel of the plurality of channels corresponding to the output frequency band thus found to said voltage controlled oscillator; and
said phase-locked loop circuit controls said voltage controlled oscillator so that the voltage controlled oscillator may provide an output signal that has the reference frequency and is in phase with the given signal.

2. The device as claimed in claim 1, wherein said adjustment unit determines a predetermined search time for the first search operation; and
said adjustment unit determines a predetermined search time for the subsequent search operation longer than the predetermined search time for the first search operation.

3. The device as claimed in claim 1, wherein said adjustment unit determines a predetermined search time for the first search operation; and
said adjustment unit determines a predetermined search time for the subsequent search operation exponentially longer than the predetermined search time for the first search operation.

4. The device as claimed in claim 2, wherein said adjustment unit comprises a timer circuit determining the predetermined search times for respective search operations; and
a counting circuit counting the reference frequency of the given signal provided from the exterior and a comparison frequency of an output signal provided from said voltage controlled oscillator in said phase-locked loop circuit, respectively, provided to said adjustment unit during the predetermined search time determined in said timer circuit.

5. The device as claimed in claim 4, wherein said timer circuit determines the predetermined search time according to an input signal provided from the exterior.

6. A self-adjustment device for adjusting a phase-locked loop circuit that comprises at least one voltage controlled oscillator having a plurality of channels corresponding to a plurality of output frequency bands comprising:
an adjustment unit dividing the plurality of output frequency bands corresponding to the plurality of channels provided from said voltage controlled oscillator into two halves, determining to which one of the two halves a reference frequency of a given signal provided from the exterior belongs, dividing the determined one of the two halves into further two halves, and repeating the determination and the division until an output frequency band that conforms to the reference frequency of the given signal is found, wherein
said adjustment unit sets an appropriate one channel of the plurality of the channels corresponding to the output frequency band thus found to said voltage controlled oscillator; and
said phase-locked loop circuit controls said voltage controlled oscillator so that the voltage controlled oscillator may provide an output signal that has the reference frequency and is in phase with the given signal.

7. A self-adjustable phase-locked loop frequency synthesizer comprising:
a phase-locked loop circuit comprising at least one voltage controlled oscillator having a plurality of channels corresponding to a plurality of output frequency bands; and
a self-adjustment device comprising an adjustment unit providing a channel selection signal to said voltage controlled oscillator so that said voltage controlled oscillator sequentially provides one of the plurality of output frequency bands having a part of each output frequency band overlapping one over the other in accordance with the channel selection signal provided from said adjustment unit, wherein,
said adjustment unit sequentially performs a plurality of search operations in order to find the output frequency band that conforms to a reference frequency of a given signal provided from the exterior;
the plurality of search operations comprises a first search operation in which the reference frequency of the given signal and the output frequency band corresponding to a first medium of the plurality of output frequency bands provided from said voltage controlled oscillator are compared and, depending on the result of the first search operation, a second search operation in which the reference frequency of the given signal and the output frequency band corresponding to a second medium of one of the halves of the plurality of output frequency bands, which halves are determined by having the output frequency band corresponding to the first medium as a center dividing the halves, are compared;
the plurality of search operations comprise further search operations subsequent to the second search operation, which further search operations are performed until the output frequency band that conforms to the reference frequency of the given signal is found;
said adjustment device sets an appropriate one channel of the plurality of channels corresponding to the output frequency band thus found to said voltage controlled oscillator; and
said phase-locked loop circuit controls said voltage controlled oscillator so that the voltage controlled oscillator may provide an output signal that has the reference frequency and in phase with the given signal.

8. A self-adjustable phase-locked loop frequency synthesizer comprising:
a phase-locked loop circuit comprising at least one voltage controlled oscillator having a plurality of channels corresponding to a plurality of output frequency bands; and
an adjustment device comprising an adjustment unit dividing the plurality of output frequency bands corresponding to the plurality of channels provided from said voltage controlled oscillator into two halves, determining to which one of the two halves a reference frequency of a given signal provided from the exterior belongs, dividing the determined one of the two halves into further two halves, and repeating the determination and the division until an output frequency band that conforms to the reference frequency of the given signal is found, wherein
said adjustment device sets an appropriate one of the plurality of channels corresponding to the output frequency band thus found to said voltage controlled oscillator; and
the phase-locked loop circuit controls said voltage controlled oscillator so that the voltage controlled oscillator may provide an output signal that has the reference frequency and is in phase with the given signal.

9. A method of adjusting a phase-locked loop circuit that comprises at least one voltage controlled oscillator having a plurality of channels corresponding to a plurality of output frequency bands comprising the steps of:
a) providing a channel selection signal to said voltage controlled oscillator in said phase-locked loop circuit so that said voltage controlled oscillator sequentially provides one of a plurality of output frequency bands having a part of each output frequency band overlapping one over the other in accordance with the channel selection signal provided; and
b) sequentially performing a plurality of search operations in order to find an output frequency band that conforms to a reference frequency of a given signal provided from the exterior, wherein said step b) comprises the sub-steps of:
c) comparing the reference frequency of the given signal and the output frequency band corresponding to a first medium of the plurality of output frequency bands and further;
d) comparing the reference frequency of the given signal and the output frequency band corresponding to a second medium of one of the halves of the plurality of output frequency bands, which halves are determined by having the output frequency band corresponding to the first medium as a center dividing the halves, depending on the result of the previous step;
e) repeating said step d) until the output frequency band that conforms to the reference frequency of the given signal is found;
f) setting an appropriate one channel of the plurality of channels corresponding to the output frequency band thus found to said voltage controlled oscillator; and
g) controlling said voltage controlled oscillator so that the voltage controlled oscillator may provide an output signal that has the reference frequency and in phase with the given signal.

10. A method of adjusting a phase-locked loop circuit that comprises at least one voltage controlled oscillator having a plurality of channels corresponding to a plurality of output frequency bands comprising the steps of:
a) dividing the plurality of output frequency bands corresponding to the plurality of channels provided from said voltage controlled oscillator into two halves;
b) determining to which one of the two halves a reference frequency of a given signal provided from the exterior belongs;
c) dividing the determined one of the two halves into further two halves;
d) repeating the step b) and the step c) until an output frequency band that conforms to the reference frequency of the given signal is found; and
e) setting an appropriate one channel of the plurality of channels corresponding to the output frequency band found in the step d) to said voltage controlled oscillator; and
f) controlling said voltage controlled oscillator so that the voltage controlled oscillator may provide an output signal that has the reference frequency and in phase with the given signal.
